(19) United States
(12) Patent Application Publication
(10) Pub. No.: US 2014/0327001 A1
(43) Pub. Date: Nov. 6, 2014

(54) METHOD FOR MANUFACTURING OXIDE SEMICONDUCTOR THIN FILM TRANSISTOR, AND ACTIVE OPERATING DISPLAY DEVICE AND ACTIVE OPERATING SENSOR DEVICE USING SAME

(71) Applicant: University-Industry Cooperation Group of Kyung Hee University, Yongin (KR)

(72) Inventors: Jin Jang, Seoul (KR); Mallory Mativenga, Seoul (KR); Dong Han Kang, Seoul (KR)

(21) Appl. No.: 14/336,716

(22) Filed: Jul. 21, 2014

Related U.S. Application Data
(63) Continuation of application No. PCT/KR2013/000378, filed on Jan. 17, 2013.

(30) Foreign Application Priority Data
Jan. 20, 2012 (KR) 10-2012-0006730

(51) Int. Cl. H01L 27/12; H01L 29/786; H01L 29/66

(52) U.S. Cl. CPC H01L 27/1296; H01L 29/66969; H01L 29/7869
USPC 257/43; 438/104

(57) ABSTRACT

The present invention relates to a method for manufacturing an oxide semiconductor thin film transistor and to an actively operating display device and actively operating sensor display device using the same. A method for manufacturing an oxide semiconductor thin film transistor includes: forming a gate electrode by depositing and patterning a gate layer over a substrate; sequentially depositing a gate insulation film, an oxide semiconductor, and an etch stopper over the gate electrode and patterning the etch stopper; patterning the oxide semiconductor; forming a source electrode and a drain electrode over the patterned oxide semiconductor; and depositing a protective layer over the source electrode and the drain electrode and forming a contact hole in the protective layer, where the oxide semiconductor is formed to a thickness that is smaller than or equal to 4 nm.

### CROSS-REFERENCE TO RELATED APPLICATIONS

This application is a continuation of International Application No. PCT/KR2013/000378 filed on Jan. 17, 2013, which claims priority to Korean Patent Application No. 10-2012-0006730 filed on Jan. 20, 2012, which applications are incorporated herein by reference.

### TECHNICAL FIELD

The present invention relates to a method for manufacturing an oxide semiconductor thin film transistor and an actively operating display device and actively operating sensor display device using the same, more particularly to a method for manufacturing an oxide semiconductor thin film transistor and an actively operating display device and actively operating sensor display device using the same that increase reliability by supplementing and improving instability against photoelectric fields.

### RELATED ART

In recent times, there have been much research and development effort directed towards the thin film transistor that uses an oxide semiconductor as an active layer. The oxide semiconductor thin film transistor is applied to flat panel displays such as those using TFT-LCD and AMOLED, various sensors, operating and logic circuits, etc., due to the advantages it provides, including high electric field mobility, a low threshold voltage near 0V, low current leakage, etc.

In spite of the above advantages, however, the oxide semiconductor thin film transistor may also entail problems regarding reliability against electric fields and reliability against photoelectric fields.

Research focused on improving reliability against electric fields have provided stabilization techniques based on improving the material used for the insulation film or the protective layer and improving the structure of the thin film transistor. However, the research efforts conducted worldwide on improving reliability against photoelectric fields have not been much fruitful.

Specifically, when a negative electric field and light are provided simultaneously, the threshold voltage of the oxide semiconductor thin film transistor may move considerably in the negative direction with the passage of time.

An oxide semiconductor thin film transistor that uses an oxide semiconductor for the active layer is an electrical element that provides benefits such as high electric field mobility, of 10 cm²/Vs or higher, and low current leakage, etc. These can be applied to displays and sensors, etc., which use a switching property, as well as to operating and logic circuits, etc.

FIG. 1 is a graph illustrating changes in the transition curve properties and electric field mobility of an oxide semiconductor thin film transistor according to the related art under a photoelectric field for a 0.1V drain voltage.

FIG. 1 shows changes in transition curve properties according to time when an electric field of −20V is applied together with light of 10,000 lux to a thin film transistor using an oxide active layer according to the related art. The graph shows the result that the instability pertaining to the movement of the threshold voltage of the transition curve when photoelectric stress is applied is not improved.

As such, there is much research being conducted on mechanisms relating to the movement of the threshold voltage, but the problem has not yet been fundamentally resolved.

### SUMMARY

An aspect of the present invention is to supplement and improve instability against photoelectric fields and thereby improve reliability by having the oxide semiconductor of the oxide semiconductor thin film transistor deposited with a small thickness.

Also, an aspect of the present invention is to improve reliability against photoelectric fields without changing or adding to the processing by adjusting the thickness of the oxide semiconductor, and thus enable application to actively operating displays, actively operating sensors, and the like.

To resolve the problems above, an embodiment of the invention provides a method for manufacturing an oxide semiconductor thin film transistor that includes: a first step of forming a gate electrode by depositing and patterning a gate layer over a substrate; a second step of sequentially depositing a gate insulation film, an oxide semiconductor, and an etch stopper over the gate electrode and patterning the etch stopper; a third step of patterning the oxide semiconductor; a fourth step of forming a source electrode and a drain electrode over the patterned oxide semiconductor; and a fifth step of depositing a protective layer over the source electrode and the drain electrode and forming a contact hole in the protective layer, where the oxide semiconductor is formed to a thickness that is smaller than or equal to 4 nm.

Another embodiment of the invention provides a method for manufacturing an oxide semiconductor thin film transistor that includes: a first step of sequentially depositing a buffer layer, an oxide semiconductor, a gate insulation film, and a gate layer over a substrate; a second step of forming a gate electrode by patterning the gate layer; a third step of patterning the oxide semiconductor; a fourth step of depositing a protective layer over the oxide semiconductor and forming a contact hole in the protective layer; and a fifth step of forming a source electrode and a drain electrode over the contact hole, where the oxide semiconductor is formed to a thickness that is smaller than or equal to 4 nm.

Still another embodiment of the invention provides a method for manufacturing an oxide semiconductor thin film transistor that includes: a first step of depositing and patterning a source electrode and a drain electrode over a substrate; a second step of depositing an oxide semiconductor, a gate insulation film, and a gate layer over the source electrode and the drain electrode; a third step of patterning the gate insulation film and the gate layer; a fourth step of patterning the oxide semiconductor; and a fifth step of depositing a protective layer over the patterned gate insulation film and the oxide semiconductor and forming a contact hole, where the oxide semiconductor is formed to a thickness that is smaller than or equal to 4 nm.

Yet another embodiment of the invention provides a method for manufacturing an oxide semiconductor thin film transistor that includes: a first step of depositing and patterning a buffer layer and an oxide semiconductor over a substrate; a second step of depositing and patterning a source electrode and a drain electrode over the oxide semiconductor; a third step of forming a gate pattern by depositing a gate insulation film and a gate layer over the source electrode and the drain electrode and patterning the gate layer; and a fourth step of forming and patterning a protective layer over the gate pattern, where the oxide semiconductor is formed to a thickness of 4 nm or smaller.

Another embodiment of the invention provides a method for manufacturing an oxide semiconductor thin film transistor that includes: a first step of forming a gate electrode by depositing and patterning a gate layer over a substrate; a second step of depositing a gate insulation film and an oxide semiconductor over the gate electrode; a third step of patterning the oxide semiconductor; a fourth step of forming a source electrode and a drain electrode over the patterned oxide semiconductor; and a fifth step of depositing a protective layer over the source electrode and the drain electrode and forming a contact hole in the protective layer, where the oxide semiconductor is formed to a thickness that is smaller than or equal to 4 nm.

Still another embodiment of the invention provides a method for manufacturing an oxide semiconductor thin film transistor that includes: a first step of forming a gate electrode by depositing and patterning a gate layer over a substrate; a second step of depositing a gate insulation film, a source electrode, and a drain electrode over the gate electrode; a third step of patterning the source electrode and the drain electrode; a fourth step of depositing and patterning an oxide semiconductor over the patterned source electrode and drain electrode; and a fifth step of depositing a protective layer over the patterned oxide semiconductor and forming a contact hole in the protective layer, where the oxide semiconductor is formed to a thickness that is smaller than or equal to 4 nm.

An actively operating display device including an oxide semiconductor thin film transistor based on an embodiment of the invention may be manufactured according to one of the methods set forth above.

Also, an actively operating sensor device including an oxide semiconductor thin film transistor based on an embodiment of the invention may be manufactured according to one of the methods set forth above.

According to an embodiment of the invention, the oxide semiconductor in an oxide semiconductor thin film transistor can be deposited with a small thickness, whereby the instability against photoelectric fields can be supplemented and improved for greater reliability.

Also, according to an embodiment of the invention, the reliability against photoelectric fields can be improved, without changing or adding to the processing, by adjusting the thickness of the oxide semiconductor, enabling applications to actively operating displays, actively operating sensors, and the like.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a graph illustrating changes in the transition curve properties and electric field mobility of an oxide semiconductor thin film transistor according to the related art under a photoelectric field for a 0.1V drain voltage.

FIG. 2A, FIG. 2B, FIG. 2C, FIG. 2D, and FIG. 2E illustrate a method of manufacturing an oxide semiconductor thin film transistor according to an embodiment of the invention.

FIG. 3A and FIG. 3B illustrate a method of manufacturing an oxide semiconductor thin film transistor according to another embodiment of the invention.

FIG. 4A, FIG. 4B, FIG. 4C, FIG. 4D, and FIG. 4E illustrate a method of manufacturing an oxide semiconductor thin film transistor according to still an embodiment of the invention.

FIG. 5, FIG. 6, FIG. 7, and FIG. 8 illustrate a method of manufacturing an oxide semiconductor thin film transistor according to yet another embodiment of the invention.

FIG. 9A is a graph illustrating the current and voltage properties of an oxide semiconductor thin film transistor according to an embodiment of the invention.

FIG. 9B is a graph illustrating the output properties of an oxide semiconductor thin film transistor according to an embodiment of the invention.

FIG. 10A is a graph illustrating changes in the transition curve properties and electric field mobility of an oxide semiconductor thin film transistor according to an embodiment of the invention under a photoelectric field for a 0.1V drain voltage.

FIG. 10B is a graph comparing the output properties of an oxide semiconductor thin film transistor according to an embodiment of the invention before and after photoelectric stress.

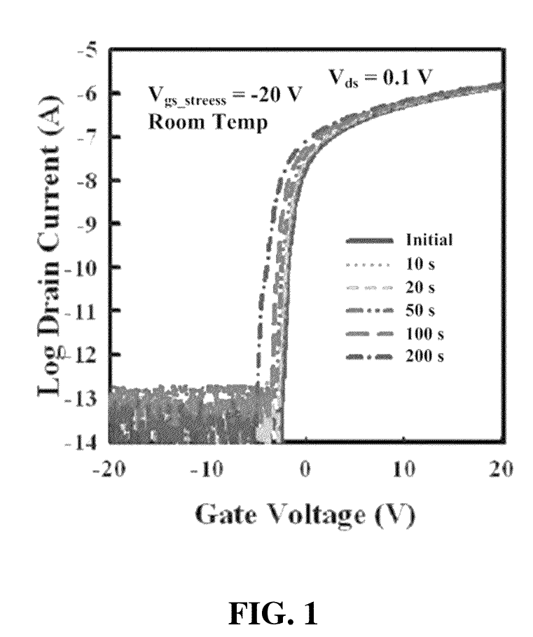

### DETAILED DESCRIPTION

In the following, a detailed description is provided, with reference to the accompanying drawings, for a lighting member based on a preferred mode of practice. In describing the mode of practice, certain descriptions may be omitted for well-known functions or components if they are deemed to unnecessarily obscure the essence of the present invention. Also, the components shown in the drawings may be exaggerated in size for the sake of easier description and understanding; their relative sizes may differ in actual application.

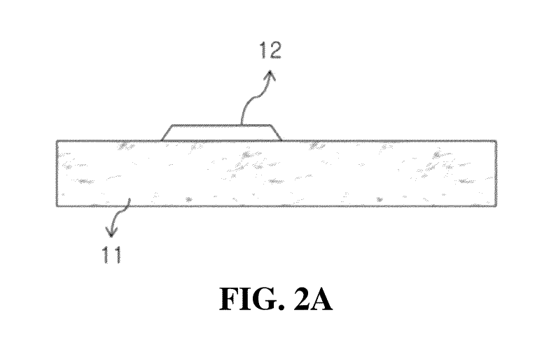

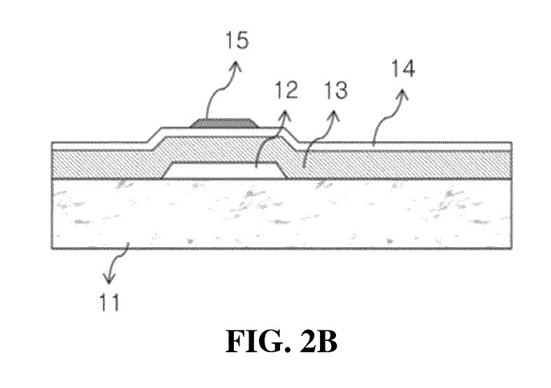

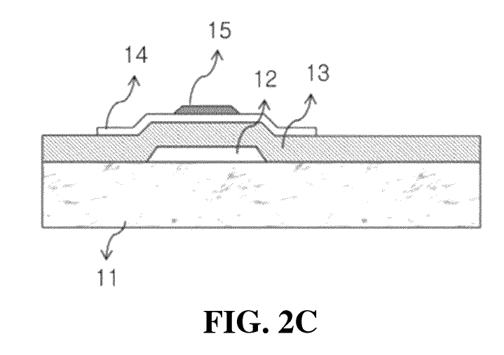

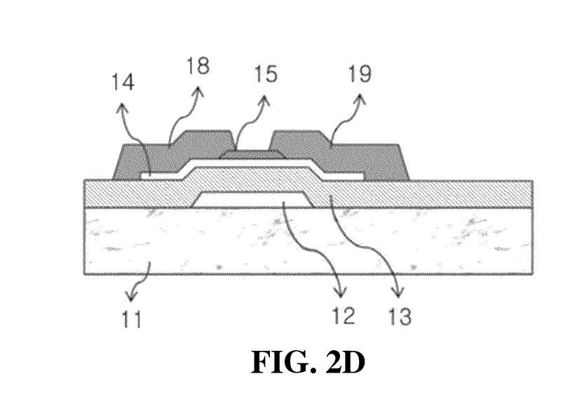

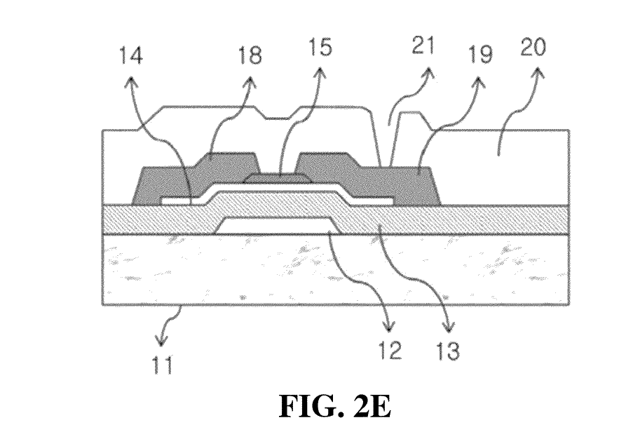

FIG. 2A through FIG. 2E illustrate a method of manufacturing an oxide semiconductor thin film transistor according to an embodiment of the invention.

A method for manufacturing an oxide semiconductor thin film transistor according to an embodiment of the invention is described below with reference to FIGS. 2A to 2e.

After depositing a gate electrode 12 over a substrate 11 as illustrated in FIG. 2A, a gate insulation film 13 may be formed over the gate electrode 12 as illustrated in FIG. 2B.

Here, the substrate 11 can be formed as a glass substrate, a plastic substrate, a silicon substrate, or a polymer material formed over the glass substrate, and can also be formed to have an oxidation protection layer deposited over the substrate 11.

Also, the gate insulation film 13 can be formed as a silicon oxide film or a silicon nitride film.

Then, an oxide semiconductor 14 may be formed over the gate insulation film 13, an etch stopper 15 may be formed deposited over the oxide semiconductor 14, and the oxide semiconductor 14 may be patterned as illustrated in FIG. 2C.

Here, it may be desirable to form the oxide semiconductor 14 to a thickness that is smaller than or equal to 4 nm.

Thus, according to an embodiment of the invention, the oxide semiconductor 14 may be formed to a thickness of 4 nm or smaller, and as the oxide semiconductor is deposited with a small thickness, the instability to photoelectric fields can be supplemented and improved, for increased reliability.

An oxide semiconductor 14 in an embodiment of the invention can include any one of indium gallium zinc oxide (Amorphous-InGaZnO4), zinc oxide (ZnO), indium zinc oxide (IZO), indium tin oxide (ITO), zinc tin oxide (ZTO), gallium zinc oxide (GZO), hafnium indium zinc oxide (HIZO), zinc indium tin oxide (ZITO) and aluminum zinc tin oxide (AZTO) in an amorphous or a polycrystalline form.

Then, a source electrode 18 and a drain electrode 19 may be formed over the patterned oxide semiconductor, as illustrated in FIG. 2D, a protective layer 20 may be deposited over the source electrode 18 and drain electrode 19, and a contact hole 21 may be formed in the protective layer 20.

Here, the source electrode 18 and the drain electrode 19 can include molybdenum (Mo) or indium tin oxide (ITO), and the protective layer 20 can be formed as a silicon oxide film or a silicon nitride film.

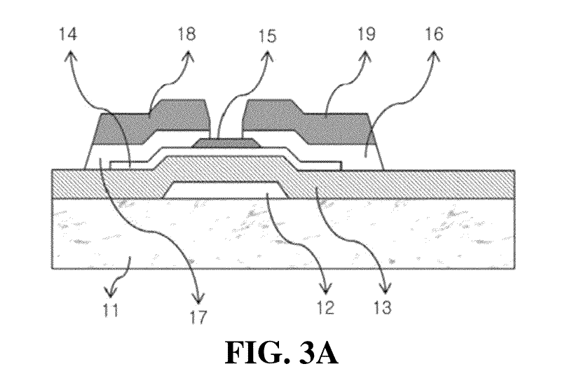

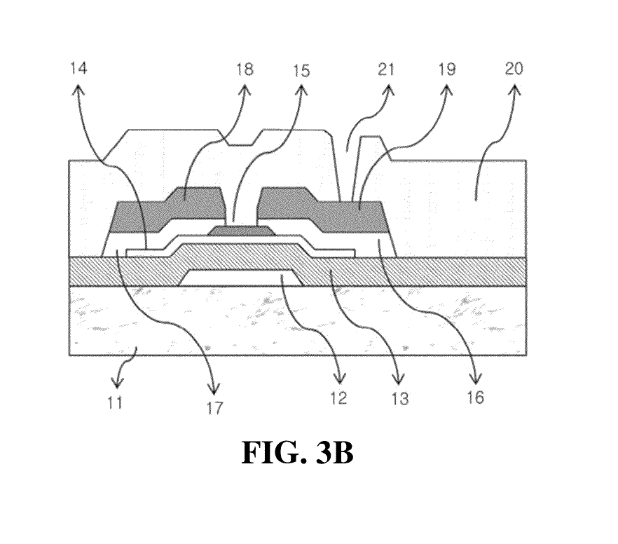

FIG. 3A and FIG. 3B illustrate a method of manufacturing an oxide semiconductor thin film transistor according to another embodiment of the invention.

As illustrated in FIG. 3A, a gate electrode 12 may be deposited over a substrate 11, and a gate insulation film 13 may be formed over the gate electrode 12. Here, the substrate 11 can be formed as a glass substrate, a plastic substrate, a silicon substrate, or a polymer material formed over the glass substrate, and can also be formed to have an oxidation protection layer deposited over the substrate 11. The gate insulation film 13 can be formed as a silicon oxide film or a silicon nitride film.

Then, an oxide semiconductor 14 may be formed over the gate insulation film 13, an etch stopper 15 may be deposited over the oxide semiconductor 14, and the oxide semiconductor 14 may be patterned. Here, it may be desirable to have the oxide semiconductor 14 deposited to a thickness of two or three layers of the molecules of which the oxide semiconductor is composed, with the oxide semiconductor formed to a thickness of 4 nm or smaller.

Similarly to the embodiment illustrated in FIGS. 2A to 2E, the embodiment illustrated in FIGS. 3A and 3B can also have the oxide semiconductor deposited with a small thickness, so that the instability to photoelectric fields can be supplemented and improved, for increased reliability.

An oxide semiconductor 14 in an embodiment of the invention can include any one of indium gallium zinc oxide (Amorphous-InGaZnO4), zinc oxide (ZnO), indium zinc oxide (IZO), indium tin oxide (ITO), zinc tin oxide (ZTO), gallium zinc oxide (GZO), hafnium indium zinc oxide (HIZO), zinc indium tin oxide (ZITO) and aluminum zinc tin oxide (AZTO) in an amorphous or a polycrystalline form.

Then, in the embodiment of FIG. 3A, a second oxide semiconductor 16 may be deposited over the oxide semiconductor 14 and the etch stopper 15. In order to improve the current and voltage properties of the oxide semiconductor thin film transistor, the second oxide semiconductor 16 may be deposited with a large thickness of 20 nm over the very thin oxide semiconductor 14 in the ohmic region.

Then, as illustrated in FIG. 3B, a source electrode 18 and a drain electrode 19 may be formed over the second oxide semiconductor 16, a protective layer 20 may be deposited over the source electrode 18 and drain electrode 19, and a contact hole 21 may be formed in the protective layer 20.

Here, the source electrode and the drain electrode can include molybdenum (Mo) or indium tin oxide (ITO), and the protective layer 20 can be formed as a silicon oxide film or a silicon nitride film.

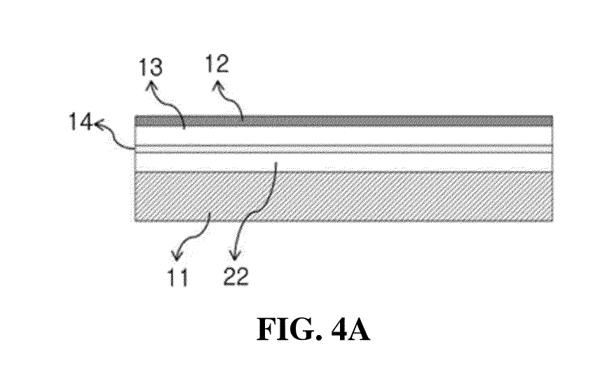

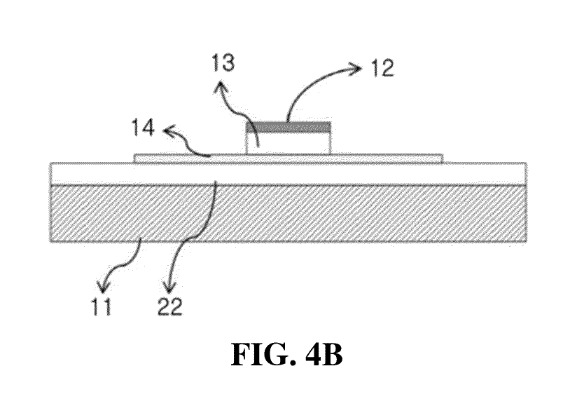

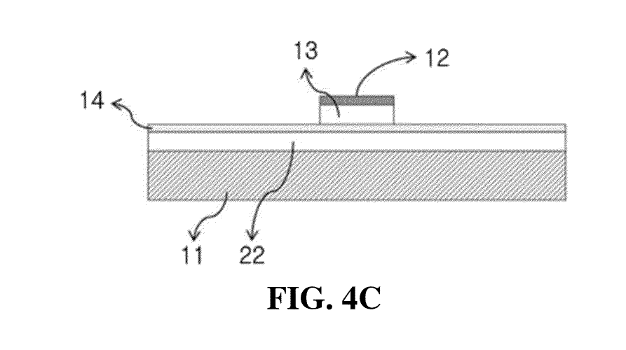

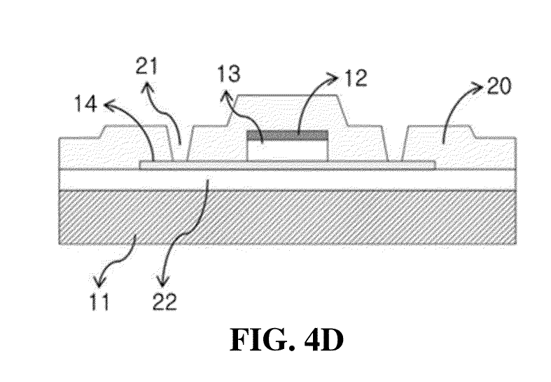

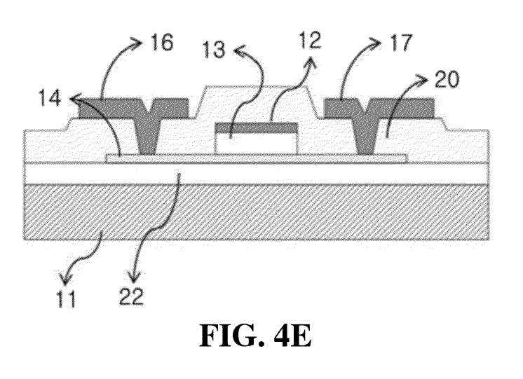

FIG. 4A through FIG. 4E illustrate a method of manufacturing an oxide semiconductor thin film transistor according to still an embodiment of the invention.

First, a buffer layer 22, an oxide semiconductor 14, a gate insulation film 13, and a gate layer 12 may be deposited sequentially over a substrate 11, as illustrated in FIG. 4A.

Here, the oxide semiconductor 14 can be deposited to a thickness of two or three layers of the molecules of which the oxide semiconductor is composed, to form a thickness smaller than or equal to 3 nm or 4 nm, and as the oxide semiconductor is thus deposited with a small thickness, the instability to photoelectric fields can be supplemented and improved, for increased reliability.

Then, as illustrated in FIG. 4B, a gate electrode 12 may be formed by patterning the gate layer, and as illustrated in FIG. 4C, the oxide semiconductor 14 may be patterned.

Then, as illustrated in FIG. 4D, a protective layer 20 may be deposited, and contact holes 21 may be formed in the protective layer 20, and as illustrated in FIG. 4E, a source electrode 16 and a drain electrode 17 may be formed over the contact holes 21 of the protective layer 20.

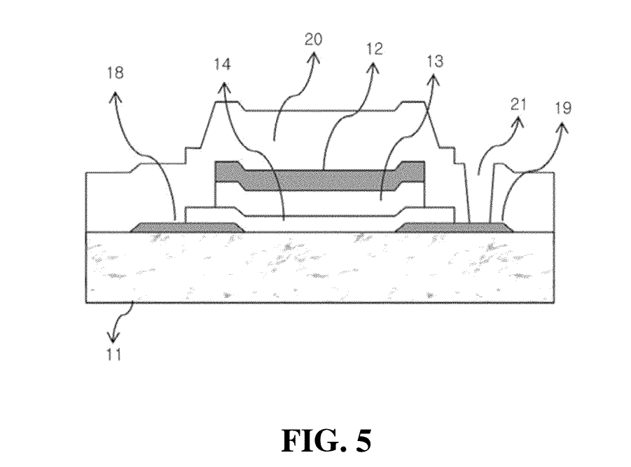

FIG. 5 through FIG. 8 illustrate a method of manufacturing an oxide semiconductor thin film transistor according to yet another embodiment of the invention.

To be more specific, FIG. 5 shows an embodiment for an oxide semiconductor thin film transistor that has an active layer having a thickness of 3 nm or smaller and has a top gate, bottom contact configuration.

Looking at the embodiment in more detail, a source electrode 18 and a drain electrode 19 may be deposited and patterned over a substrate 11, and an oxide semiconductor 14, a gate insulation film 13, and a gate layer may be deposited over the source electrode 18 and the drain electrode 19. Then, the gate layer 12 may be patterned, and the gate insulation film 13 may be patterned. Then, a protective layer 20 may be deposited over the patterned gate insulation film 13 and the oxide semiconductor 14, and a contact hole 21 may be formed.

FIG. 6 shows an embodiment for an oxide semiconductor thin film transistor that has an active layer having a thickness of 3 nm or smaller and has a top gate, top contact configuration.

Looking at the embodiment in more detail, a buffer layer and an oxide semiconductor 14 may be deposited and patterned over a substrate 11, and a source electrode 18 and a drain electrode 19 may be deposited and patterned over the oxide semiconductor 14. A gate insulation film 13 and a gate layer may be deposited over the source electrode 18 and the drain electrode 19, and the gate layer may be patterned to form a gate pattern 12. Then, a protective layer 20 may be formed and patterned over the gate pattern 12.

FIG. 7 shows an embodiment for an oxide semiconductor thin film transistor that has an active layer having a thickness of 3 nm or smaller and has a bottom gate, top contact configuration.

Looking at the embodiment in more detail, a gate electrode 12 may be formed by depositing and patterning a gate layer over a substrate 11, and a gate insulation film 13 and an oxide semiconductor 14 may be deposited over the gate electrode 12. Then, the oxide semiconductor 14 may be patterned, and a source electrode 18 and a drain electrode 19 may be formed over the patterned oxide semiconductor 14. A protective layer 20 may be deposited over the source electrode 18 and the drain electrode 19, and a contact hole 21 may be formed in the protective layer 20.

FIG. 8 shows an embodiment for an oxide semiconductor thin film transistor that has an active layer having a thickness of 3 nm or smaller and has a bottom gate, bottom contact configuration.

Looking at the embodiment in more detail, a gate electrode 12 may be formed by depositing and patterning a gate layer over a substrate 11; a gate insulation film 13, a source electrode 18, and a drain electrode 19 may be deposited over the gate electrode 12; and the source electrode 18 and the drain electrode may be patterned. Then, an oxide semiconductor 14 may be deposited and patterned over the patterned source electrode 18 and drain electrode 19; a protective layer 20 may be deposited over the patterned oxide semiconductor 14; and a contact hole 21 may be formed in the protective layer 20.

An oxide semiconductor thin film transistor according to an embodiment of the invention as illustrated in FIGS. 5 to 8 above may have the structure of a regular thin film transistor, but the oxide semiconductor 14 may be formed to a thickness of two or three layers of the molecules of which the oxide semiconductor is composed, such that the oxide semiconductor is formed to a thickness smaller than or equal to 3 nm or 4 nm.

Thus, similarly to the embodiments described above, the oxide semiconductor can be deposited with a small thickness, so that the instability to photoelectric fields can be supplemented and improved, for increased reliability.

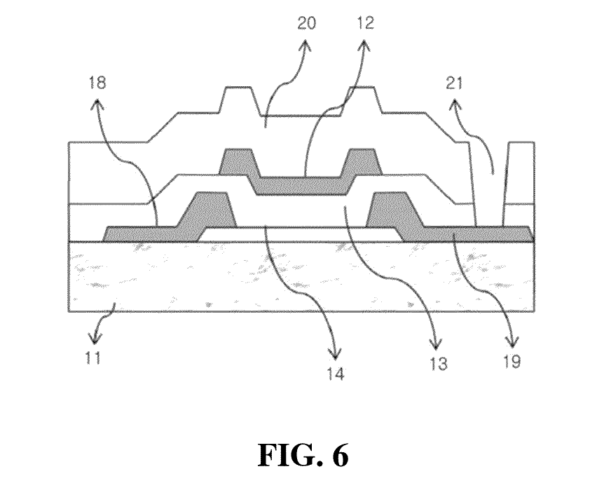

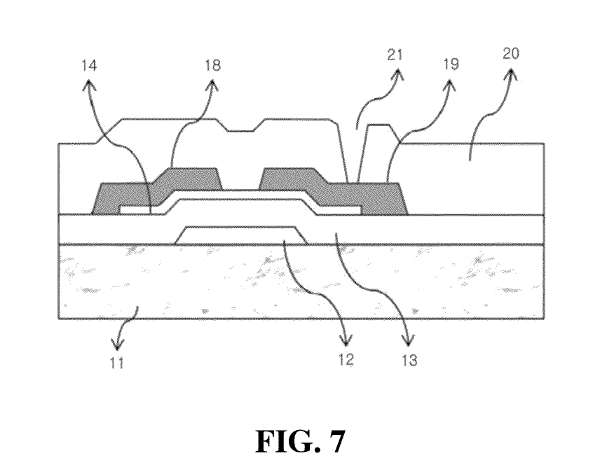

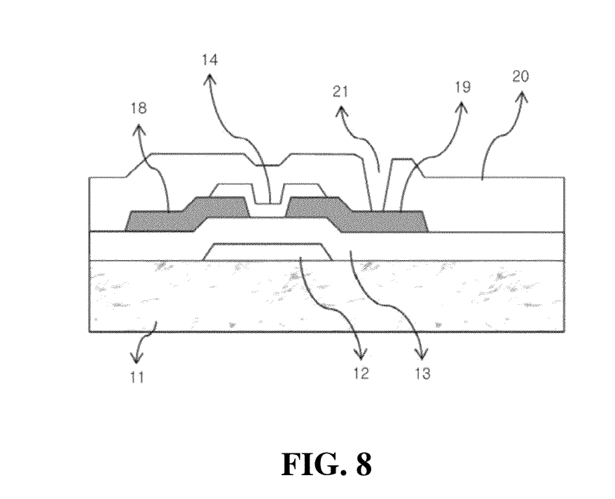

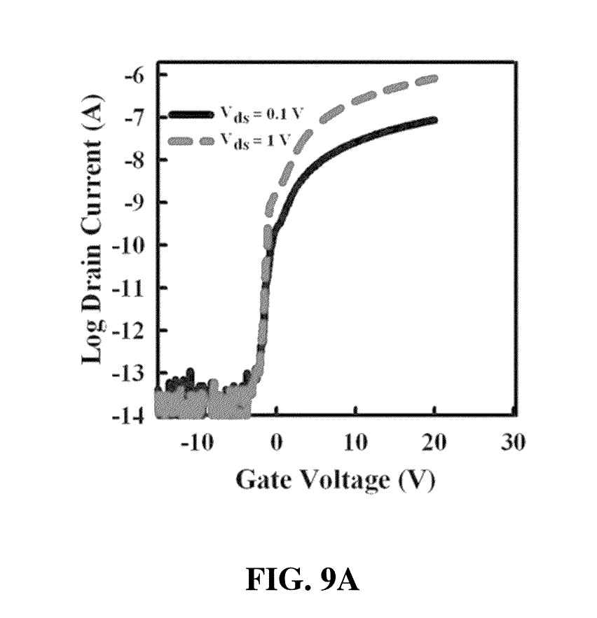

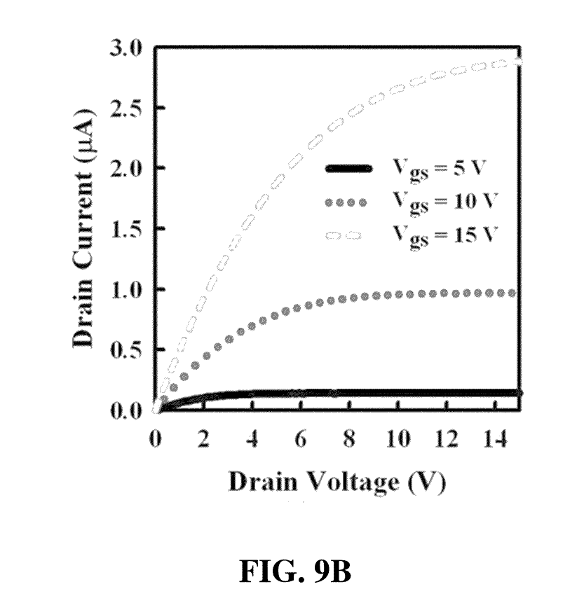

FIG. 9A is a graph illustrating the current and voltage properties of an oxide semiconductor thin film transistor according to an embodiment of the invention, and FIG. 9B is a graph illustrating the output properties of an oxide semiconductor thin film transistor according to an embodiment of the invention.

More specifically, FIG. 9A shows the current and voltage properties of an oxide semiconductor thin film transistor having a 3 nm thick active layer, and FIG. 9B shows the output properties of an oxide semiconductor thin film transistor having a 3 nm thick active layer.

FIG. 9A shows the current and voltage properties of an oxide semiconductor thin film transistor having an active layer when the drain voltage is 0.1V and 1V. From the graphs of FIGS. 9A and 9B, it can be seen that the functions of a thin film transistor is implemented to a sufficient degree, even though a very thin oxide semiconductor active layer of 3 nm is being used.

That is, as the thin film transistor using a very thin oxide semiconductor active layer of 3 nm allows the flow of a current amounting to several μA, it can sufficiently implement the properties of a switching element.

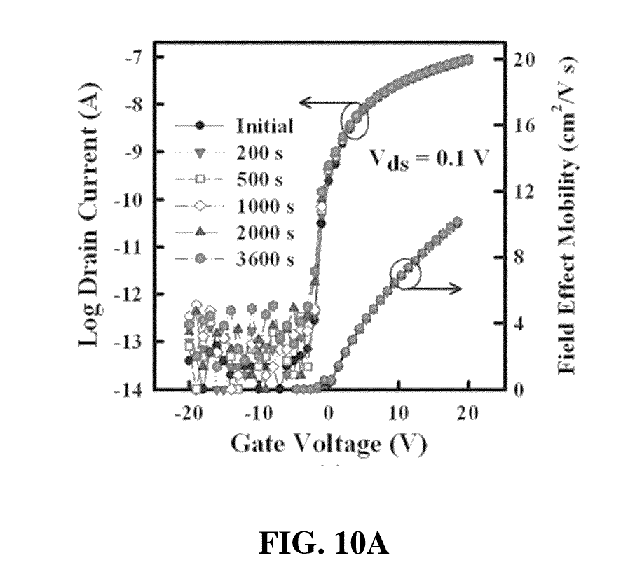

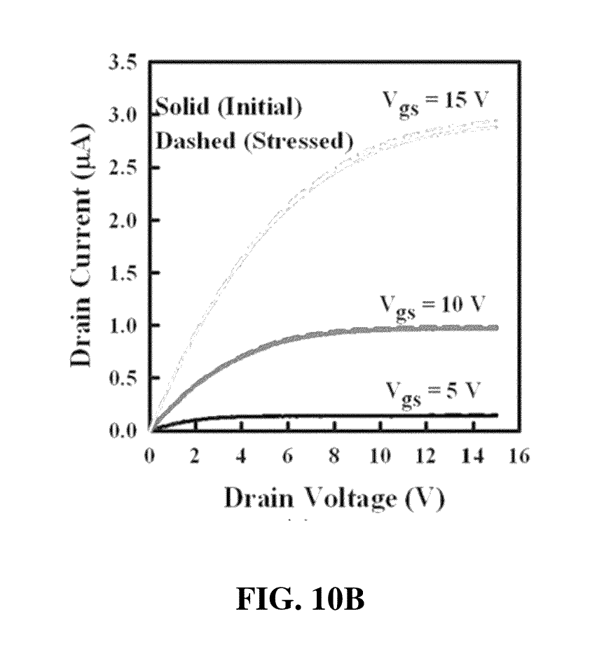

FIG. 10A is a graph illustrating changes in the transition curve properties and electric field mobility of an oxide semiconductor thin film transistor according to an embodiment of the invention under a photoelectric field for a 0.1V drain voltage, and FIG. 10B is a graph comparing the output properties of an oxide semiconductor thin film transistor according to an embodiment of the invention before and after photoelectric stress.

More specifically, FIG. 10A shows the changes in the transition curve properties and electric field mobility of an oxide semiconductor thin film transistor having a 3 nm thick active layer under a photoelectric field for a drain voltage of 0.1V, and FIG. 10B compares the output properties of an oxide semiconductor thin film transistor having a 3 nm thick active layer before and after photoelectric stress.

FIG. 10A shows changes in the transition curves according to time when an electric field of −20V was applied in white light having a luminous intensity of 10,000 lux. With a regular oxide semiconductor thin film transistor, the photoelectric field conditions above would result in a change in threshold voltage of −5V or −10V or more with the passage of time. In contrast, the oxide semiconductor thin film transistor having an active layer thickness of 3 nm according to an embodiment of the invention shows no change in threshold voltage even with photoelectric stress.

Also, FIG. 10B shows the output properties of an oxide semiconductor thin film transistor having an active layer of 3 nm, before and after photoelectric stress is applied. Not only is there no movement of the threshold voltage after photoelectric stress is applied, but also there is no change in current, meaning that there is high stability in the photoelectric properties.

Particular embodiments of the invention are described above. However, numerous variations can be derived without departing from the scope of the present invention. The technical spirit of the present invention is not to be limited to the embodiments of the invention described above, but is to be defined by the scope of claims as well as the equivalents of the claims.

1. A method for manufacturing an oxide semiconductor thin film transistor, the method comprising:
a first step of forming a gate electrode by depositing and patterning a gate layer over a substrate;
a second step of sequentially depositing a gate insulation film, an oxide semiconductor, and an etch stopper over the gate electrode and patterning the etch stopper;
a third step of patterning the oxide semiconductor;
a fourth step of forming a source electrode and a drain electrode over the patterned oxide semiconductor; and
a fifth step of depositing a protective layer over the source electrode and the drain electrode and forming a contact hole in the protective layer,
wherein the oxide semiconductor has a thickness smaller than or equal to 4 nm.

2. The method of claim 1, wherein the thickness of the oxide semiconductor is smaller than or equal to 3 nm.

3. The method of claim 1, wherein a second oxide semiconductor is deposited over the oxide semiconductor and the etch stopper.

4. The method of claim 1, further comprising, before the first step:
depositing a silicon oxidation protection film over the substrate.

5. The method of claim 1, wherein the oxide semiconductor includes any one of indium gallium zinc oxide (Amorphous-InGaZnO4), zinc oxide (ZnO), indium zinc oxide (IZO), indium tin oxide (ITO), zinc tin oxide (ZTO), gallium zinc oxide (GZO), hafnium indium zinc oxide (HIZO), zinc indium tin oxide (ZITO) and aluminum zinc tin oxide (AZTO) in an amorphous or a polycrystalline form.

6. The method of claim 1, wherein the gate insulation film and the protective layer are formed as a silicon oxide film or a silicon nitride film.

7. The method of claim 1, wherein the substrate is formed as a glass substrate, a plastic substrate, a silicon substrate, or a polymer material formed over the glass substrate, and the source electrode and the drain electrode are formed including molybdenum (Mo) or indium tin oxide (ITO).

8. A method for manufacturing an oxide semiconductor thin film transistor, the method comprising:
a first step of sequentially depositing a buffer layer, an oxide semiconductor, a gate insulation film, and a gate layer over a substrate;
a second step of forming a gate electrode by patterning the gate layer;
a third step of patterning the oxide semiconductor;
a fourth step of depositing a protective layer over the oxide semiconductor and forming a contact hole in the protective layer; and
a fifth step of forming a source electrode and a drain electrode over the contact hole,
wherein the oxide semiconductor has a thickness smaller than or equal to 4 nm.

9-12. (canceled)

13. A method for manufacturing an oxide semiconductor thin film transistor, the method comprising:
a first step of depositing and patterning a source electrode and a drain electrode over a substrate;
a second step of depositing an oxide semiconductor, a gate insulation film, and a gate layer over the source electrode and the drain electrode;
a third step of patterning the gate insulation film and the gate layer;
a fourth step of patterning the oxide semiconductor; and
a fifth step of depositing a protective layer over the patterned gate insulation film and the oxide semiconductor and forming a contact hole,
wherein the oxide semiconductor has a thickness smaller than or equal to 4 nm.

14-17. (canceled)

18. A method for manufacturing an oxide semiconductor thin film transistor, the method comprising:
a first step of depositing a buffer layer and an oxide semiconductor over a substrate and patterning the oxide semiconductor;
a second step of depositing and patterning a source electrode and a drain electrode over the oxide semiconductor;
a third step of forming a gate pattern by depositing a gate insulation film and a gate layer over the source electrode and the drain electrode and patterning the gate layer; and
a fourth step of forming and patterning a protective layer over the gate pattern,
wherein the oxide semiconductor has a thickness smaller than or equal to 4 nm.

19-22. (canceled)

23. A method for manufacturing an oxide semiconductor thin film transistor, the method comprising:
a first step of forming a gate electrode by depositing and patterning a gate layer over a substrate;
a second step of depositing a gate insulation film and an oxide semiconductor over the gate electrode;
a third step of patterning the oxide semiconductor;
a fourth step of forming a source electrode and a drain electrode over the patterned oxide semiconductor; and
a fifth step of depositing a protective layer over the source electrode and the drain electrode and forming a contact hole in the protective layer,
wherein the oxide semiconductor has a thickness smaller than or equal to 4 nm.

24-27. (canceled)

28. A method for manufacturing an oxide semiconductor thin film transistor, the method comprising:
a first step of forming a gate electrode by depositing and patterning a gate layer over a substrate;
a second step of depositing a gate insulation film, a source electrode, and a drain electrode over the gate electrode;
a third step of patterning the source electrode and the drain electrode;
a fourth step of depositing and patterning an oxide semiconductor over the patterned source electrode and drain electrode; and
a fifth step of depositing a protective layer over the patterned oxide semiconductor and forming a contact hole in the protective layer,
wherein the oxide semiconductor has a thickness smaller than or equal to 4 nm.

29-32. (canceled)

33. A thin film transistor comprising a substrate, a gate electrode, a source electrode, a drain electrode, and an oxide semiconductor, wherein the oxide semiconductor has a thickness smaller than or equal to 4 nm.

34. (canceled)
